(19) United States
(12) Patent Application Publication
(10) Pub. No.: US 2025/0385132 A1
(43) Pub. Date: Dec. 18, 2025

(54) METHODS OF FORMING CONDUCTIVE LINES TO REDUCE TIER DEFLECTION

(71) Applicant: Micron Technology, Inc., Boise, ID (US)

(72) Inventor: Everett Allen McTeer, Eagle, ID (US)

(21) Appl. No.: 19/226,820

(22) Filed: Jun. 3, 2025

Related U.S. Application Data
(60) Provisional application No. 63/658,986, filed on Jun. 12, 2024.

(51) Int. Cl. H01L 21/768; C23C 16/02; C23C 16/04; C23C 16/06

(52) U.S. Cl. CPC H01L 21/76877; C23C 16/06; C23C 16/045; C23C 16/0227; H01L 21/76802

(57) ABSTRACT

A method includes forming a tier stack of an electronic circuit including a plurality of tiers. A tier includes a first layer of dielectric material, a second layer of dielectric material, and a third layer of dielectric material. The third layer is situated between the first and second layers. The method further includes forming a void by selectively etching the second layer. The method further includes forming a nucleation layer on a first surface of the first layer. The first surface defines a first side of the void. The method further includes filling the void with metal by forming, on the nucleation layer, a first metal layer within the tier. The first metal layer is grown from the nucleation layer toward a second surface of an adjacent first layer of an adjacent tier. The second surface defines a second side of the void and is opposite the first surface.

### RELATED APPLICATION

This application claims the benefit of U.S. Provisional Patent Application No. 63/658,986, filed June 12, 2024, the entire content of which is incorporated by reference herein.

### TECHNICAL FIELD

Embodiments of the disclosure relate generally to memory sub-systems, and more specifically, relate to methods of forming conductive lines to reduce tier deflection.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A-E are schematic representations illustrating a method of forming conductive lines of a memory array in accordance with some embodiments of the present disclosure.

FIGS. 2A-D are schematic representations illustrating a method of forming conductive lines of a memory array in accordance with some embodiments of the present disclosure.

FIGS. 3A-C are flow diagrams of example methods of forming conductive lines of a memory array in accordance with some embodiments of the present disclosure.

FIG. 4A illustrates an example computing system that includes a memory sub-system in accordance with some embodiments of the present disclosure.

FIG. 4B is a block diagram of a memory device in communication with a memory sub-system controller of a memory sub-system, according to an embodiment.

### DETAILED DESCRIPTION

Aspects of the present disclosure are directed to methods of forming conductive lines (e.g., wordlines) of a memory array to reduce tier deflection. Storage devices such as solid-state drives (SSDs) may include 3-dimensional (3D) NAND flash memory technology. Traditional NAND flash memory stores data in a 2-dimensional (2D) structure, where memory cells are laid out on a single layer of dielectric material. 3-dimensional (3D) NAND instead stacks memory cells vertically in multiple layers (hence the “3D” designation). Such vertical stacking allows for increased storage densities and greater storage capacity in a comparatively smaller physical footprint when compared to planar NAND. A key advantage of 3D NAND is its ability to continue increasing storage capacities while maintaining or even improving performance and reliability. 3D NAND technology has enabled the development of SSDs with larger capacities, faster speeds, and lower costs per unit of storage.

A 3D NAND device includes multiple memory cells stacked vertically in multiple tiers, such that an inner tier of the stack is adjacent to two neighboring tiers, while an outer tier of the stack is adjacent to one neighboring tier. In order to achieve higher storage capacities and/or improve performance of the device, the number of tiers within a single memory device may be increased, thus allowing for higher-capacity storage devices. However, the increase in the number of tiers also increases the overall height of the 3D NAND structure. To limit the height of the 3D NAND structure, the thickness of each tier can be decreased.

Each tier in a 3D NAND structure can include multiple layers. For example, a tier can include an oxide layer (e.g., a metalloid oxide layer such as a silicon oxide layer) and a nitride layer (e.g., a metalloid nitride layer such as a silicon nitride layer). To increase the number of tiers in a 3D NAND structure without increasing the overall height of the structure, the thickness of each layer in the tiers making up the 3D NAND structure can be decreased. However, as the layer thickness is decreased, tier deflection can be induced. Tier deflection is the deformation of conductive lines and/or other elements of a 3D NAND structure caused by the surface tension in the metal used to form the conductive lines in the 3D NAND structure. For example, to form wordlines in a layer stack of tiers, the nitride layers are selectively etched away to form voids in the tier stack. Metal is provided into the voids (e.g., between oxide layers) to fill the voids and to form metal layers within the tier stack. The metal may be provided into the voids by a gas phase reaction mechanism. During formation of the metal layers, the metal nucleates and grows from both a top surface and a bottom surface defining each of the voids. Growth of the metal from both the top and bottom causes surface tension in the metal to act upon the oxide layers, thus pulling the oxide layers together, which causes the deformation (“deflection”) of oxide layers, which in turn may cause the deformation of the metal layer Thus, the metal layer can become “pinched off” by the deformed oxide layers, thus preventing the void from being properly filled with metal. Further, alternating layers of metal and oxide (e.g., silicon oxide) can have non-uniform thicknesses, which can cause defects and/or inefficiencies in the operation of the 3D NAND.

Aspects of the present disclosure can address the deficiencies described above and other challenges by providing methods to reduce tier deflection during the formation of conductive lines (e.g., wordlines) in a 3D NAND structure. In some embodiments, a metal layer is formed in a tier and caused to grow in a single direction (e.g., from the bottom of a void or from the top of the void). By causing the metal layer to grow in a single direction, surface tension does not act on both top and bottom surfaces defining the void, so the layers adjacent to the void are not pulled together. Therefore, the effects of surface tension in the metal can be mitigated, which would allow the metal layer to form without deflection in the adjacent oxide layers.

In some embodiments, the metal layer is formed on a nucleation layer, which, in turn, is formed on one side of the void (e.g., a bottom side, or a top side, etc.). In some embodiments, a tier includes a sacrificial layer that is used for forming the nucleation layer. In some embodiments, the nucleation layer is formed on an oxide layer. More details regarding the sacrificial layer, the nucleation layer, and the oxide layer are described herein below. The nucleation layer can be formed by selectively etching the sacrificial layer to form a void between the oxide and nitride layers of a tier before the nitride layer is exhumed (e.g., etched, removed, etc.) and backfilling the void with a metal or metal-nitride. Alternatively, the metal layer can be formed by introducing a metal precursor into the void (e.g., the void left when the nitride is exhumed). Introduction of the metal precursor may cause the metal to be deposited on an intermediate layer (between the oxide and nitride layers of a tier) and may form a metal-silicide layer. The metal, metal-nitride, and/or the metal-silicide layer may act as a nucleation layer on which a metal layer can be grown to form a conductive line (e.g., a wordline). By providing the nucleation layer on top of an oxide layer in a tier, the metal layer nucleates on the nucleation layer. The metal layer may not nucleate on the exposed oxide layer on the opposite side of the void because the metal will tend to naturally nucleate on the nucleation layer. The metal layer then grows from the nucleation layer toward the oxide layer on the opposite side of the void, in one direction. Thus, surface tension in the metal does not act to deflect the oxide layers which might occur in other solutions.

Advantages of the present disclosure include, for example, improved 3D NAND tier uniformity which can reduces the defect rate in a 3D NAND structure. By using the methods described herein, the thickness of each layer can be decreased without the undesired effects of tier deflection, thus allowing to increase the storage capacity without increasing the height of a 3D NAND structure. Moreover, the improved tier uniformity in a 3D NAND structure can improve the performance of a memory sub-system, leading to faster memory operations and/or decreased latency.

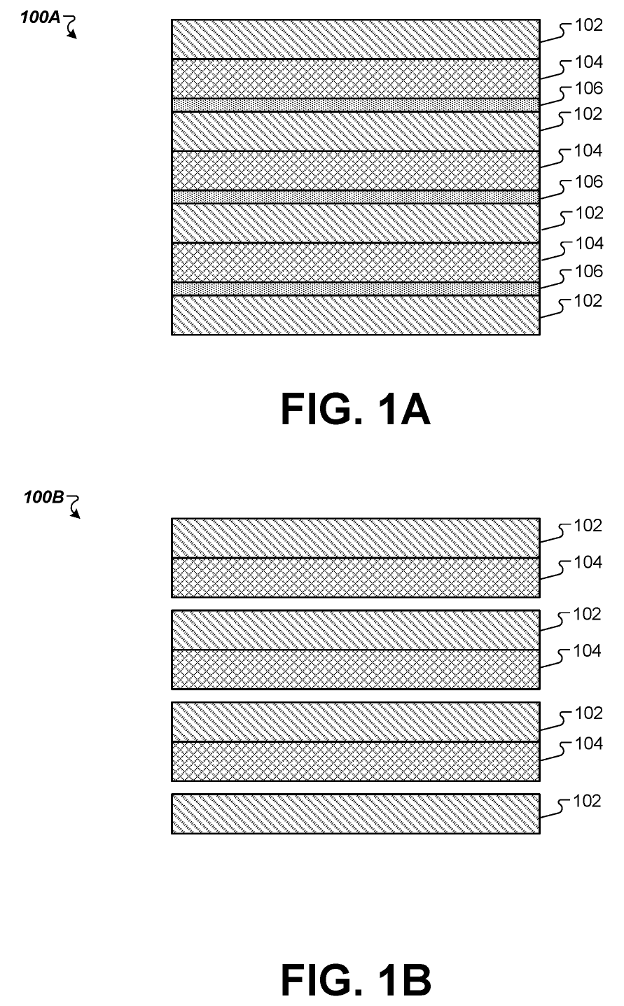

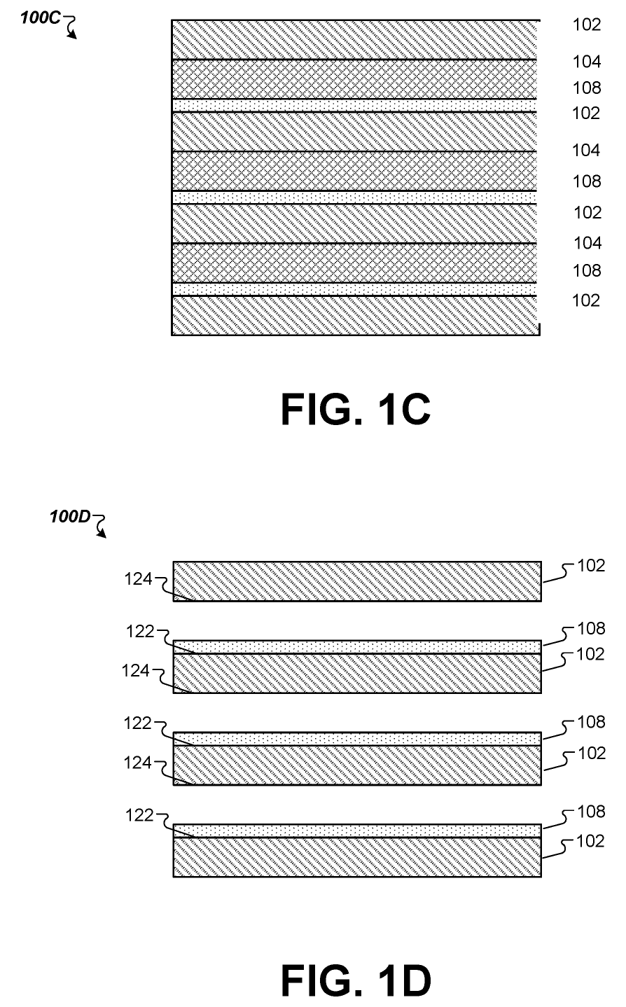

FIGS. 1A-E are schematic representations illustrating a method of forming conductive lines of a memory array in accordance with some embodiments of the present disclosure. In some embodiments, each of FIGS. 1A-E illustrate a manufacturing operation for manufacturing a memory array with reduced tier deflection as described herein.

Referring to FIG. 1A, a representation of first operation 100A is shown. In some embodiments, a tier stack is formed. The tier stack may have multiple tiers stacked vertically such that an inner tier of the stack is adjacent to two neighboring tiers, while an outer tier of the stack is adjacent to one neighboring tier. A tier may be formed by multiple layers. For example, a tier may include a first layer 102, a second layer 104, and a third layer 106. Each of the first layer 102, the second layer 104, and/or the third layer 106 may be formed of a dielectric material. The tier stack may be formed by multiple (e.g., more than one, etc.) tiers stacked one on top of the other. Illustrated in FIG. 1A, three tiers are shown, although more tiers are possible. In some embodiments, layer 102 is a metalloid oxide layer, such as a silicon oxide layer. In some embodiments, layer 104 is a metalloid nitride layer, such as a silicon nitride layer. In some embodiments, layer 106 is a sacrificial layer as will be further described herein below. In some embodiments, layer 106 is a metalloid layer such as a poly-silicon layer (e.g., a layer of substantially polycrystalline silicon, etc.) or a carbon-doped silicon nitride layer. For example, layer 106 may include silicon or carbon-doped nitride. In some embodiments, layer 106 may be a metal layer, a dielectric layer, or a semiconductor layer, etc.

In some embodiments, the stack of layers is formed by multiple deposition processes. For example, a first deposition process may be performed to deposit a first oxide layer 102, a second deposition process may be performed to deposit a first sacrificial layer 106, a third deposition process may be performed to deposit a first nitride layer 104, a fourth deposition process may be performed to deposit a second oxide layer 102, etc. The cycle of deposition processes described above may be repeated until the stack is complete. A completed stack may include many tiers, such as up to or more than one hundred tiers, etc.

Referring to FIG. 1B, a representation of a second operation 100B is shown. In some embodiments, each of the sacrificial layers 106 is selectively etched. For example, an etching operation may be performed to selectively etch poly-silicon selective to silicon nitride and/or silicon oxide to remove each of the poly-silicon layers 106 from the tier stack. The etching operation may be performed to etch poly-silicon without etching silicon nitride and/or without etching silicon oxide. Etching each of the sacrificial layers 106 may form a void in each of the tiers. The selective etching of the layers 106 may be performed by an etching process such as plasma etching. In some embodiments, process chemistries are introduced to the layers 106 to etch the layers 106. Such process chemistries can include gases such as chlorine (Cl₂), boron trichloride (BCl₃), and/or hydrogen bromide (HBr). Selective etching may include etching a first material without etching a different second material. For example, a selective etching process may be performed by etching poly-silicon material without etching silicon nitride material and/or without etching silicon oxide material.

Referring to FIG. 1C, a representation of a third operation 100C is shown. In some embodiments, the void in each of the tiers formed by the selective etching of sacrificial layers 106 is back-filled. In some embodiments, a layer 108 is formed between each of the nitride layers 104 and the oxide layers 102. In some embodiments, the layer 108 is formed by using a gas phase reaction mechanism to deposit metal or a metal-based ceramic in the voids. The gas phase reaction mechanism may include a chemical vapor deposition (CVD) technique. In some embodiments, the layer 108 is made up of titanium or titanium nitride (TiN). In some embodiments, the layer 108 forms a nucleation layer as described herein below with respect to FIG. 1E.

Referring to FIG. 1D, a representation of a fourth operation 100D is shown. In some embodiments, each of the nitride layers 104 is selectively etched. For example, an etching operation may be performed to selectively etch silicon nitride selective to silicon oxide and/or titanium nitride to remove each of the silicon nitride layers 104 from the tier stack. The etching operation may be performed to etch silicon nitride without etching silicon oxide and/or without etching titanium nitride. Etching each of the nitride layers 104 may form a void in each of the tiers. The void may be partially defined by a first surface 122 of an oxide layer 102, upon which the layer 108 may be disposed. The void may be additionally partially defined by a second surface 124 of an adjacent oxide layer 102 of an adjacent tier. The selective etching of the layers 104 may be performed by an etching process. In some embodiments, process chemistries are introduced to the layers 104 to etch the layers 104. Such process chemistries can include hydrofluoric acid (HF), phosphoric acid (H₃PO₄), hot potassium hydroxide (KOH), and/or tetramethylammonium hydroxide (TMAH).

Referring to FIG. 1E, a representation of a fifth operation 100E is shown. In some embodiments, the void in each of the tiers formed by the selective etching of nitride layer 104 is back-filled. In some embodiments, a metal layer 110 is formed between each of the oxide layers 102 and the layers 108. In some embodiments, a gas phase reaction mechanism (e.g., such as a CVD technique, etc.) is used to deposit metal between each of the layers 102 and layers 108. As mentioned herein above, each of the layers 108 may form a nucleation layer for the metal. For example, the metal carried in a gaseous precursor and provided into a void may nucleate on the layer 108. The nucleated metal crystals may be grown beginning on the nucleation layer (e.g., layer 108) on a first surface 122 that partially defines the void (e.g., the void left by the selective etching of layers 104) and may grow toward a second surface 124 that partially defines the void opposite the first surface 122. In some embodiments, the nucleated metal crystals may grow from the nucleation layer towards the adjacent oxide layer 102 as shown by the arrows in FIG. 1E. In some embodiments, the metal may does not nucleate on the adjacent oxide layer 102 because the metal will tend to naturally nucleate on the nucleation layer (e.g., layer 108). Because the metal layer grows only in one direction, surface tension in the metal may not therefore act upon the oxide layers, so the oxide layers may not be pulled towards one another. In this way, deflection of the tiers may be avoided.

In some embodiments, the metal is a conductive metal such as molybdenum, a molybdenum alloy, tungsten, and/or a tungsten alloy, etc. In some embodiments, each of the metal layers 110 is to form a conductive line in the tier stack. The conductive lines may be wordlines, such as in a memory array.

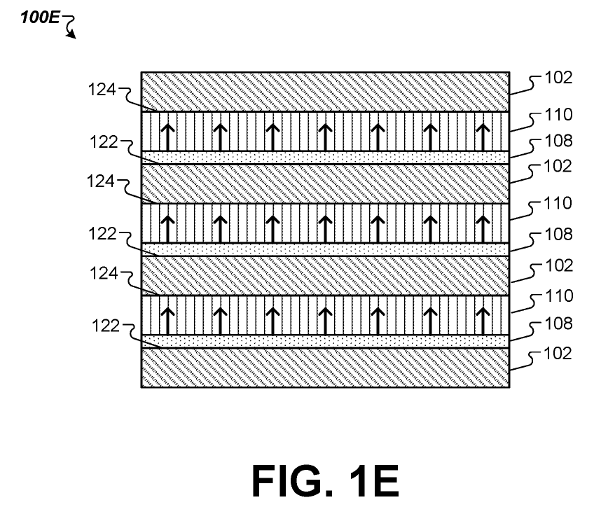

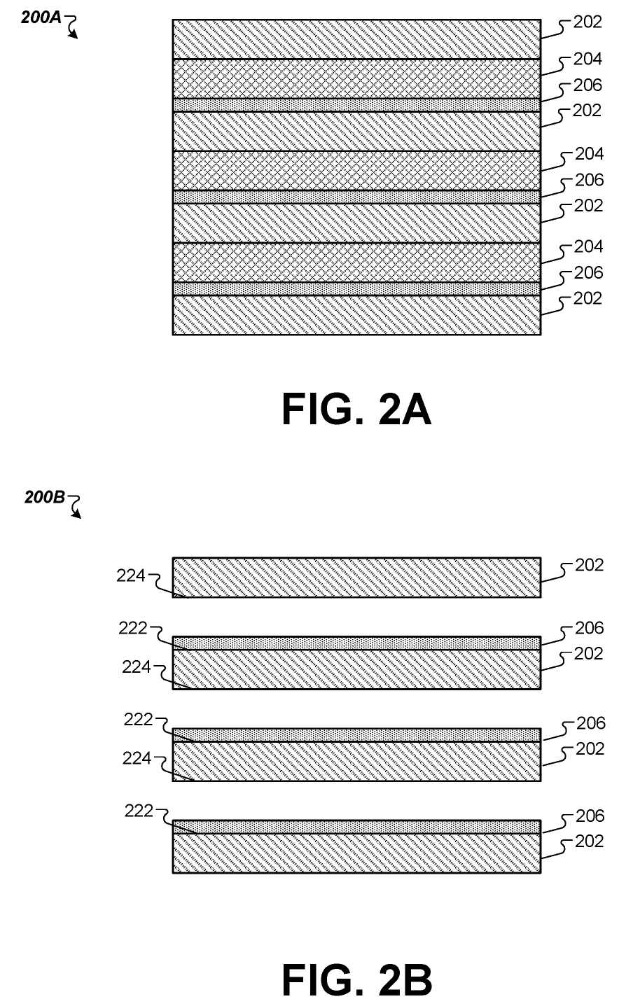

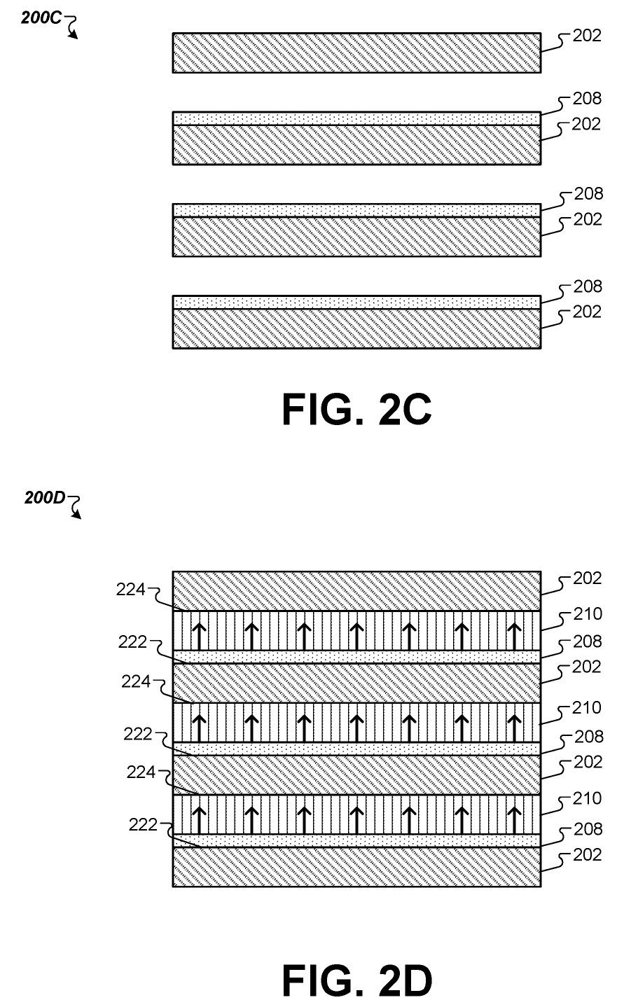

FIGS. 2A-D are schematic representations illustrating a method of forming conductive lines of a memory array in accordance with some embodiments of the present disclosure. In some embodiments, each of FIGS. 2A-D illustrate a manufacturing operation for manufacturing a memory array with reduced tier deflection as described herein.

Referring to FIG. 2A, a representation of a first operation 200A is shown. In some embodiments, a tier stack is formed. The tier stack may have multiple tiers stacked vertically such that an inner tier of the stack is adjacent to two neighboring tiers, while an outer tier of the stack is adjacent to one neighboring tier. A tier may be formed by multiple layers. For example, a tier may include a first layer 202, a second layer 204, and a third layer 206. Each of the first layer 202, the second layer 204, and/or the third layer 206 may be formed of a dielectric material. The tier stack may be formed by multiple tiers stacked one on top of the other. Illustrated in FIG. 2A, three tiers are shown, although more tiers are possible. In some embodiments, layer 202 is a metalloid oxide layer, such as a silicon oxide layer. In some embodiments, layer 204 is a metalloid nitride layer, such as a silicon nitride layer. In some embodiments, layer 206 is a metalloid layer such as a poly-silicon layer.

In some embodiments, the stack of layers is formed by multiple deposition processes. For example, a first deposition process may be performed to deposit a first oxide layer 202, a second deposition process may be performed to deposit a poly-silicon layer 206, a third deposition process may be performed to deposit a first nitride layer 204, a fourth deposition process may be performed to deposit a second oxide layer 202, etc. The cycle of deposition processes described above may be repeated until the stack is complete. A completed stack may include many tiers, such as up to or more than one hundred tiers, etc.

Referring to FIG. 2B, a representation of a second operation 200B is shown. In some embodiments, each of the nitride layers 204 is selectively etched. For example, an etching operation may be performed to selectively etch silicon nitride selective to silicon oxide and/or poly-silicon to remove each of the silicon nitride layer 204 from the tier stack. The etching operation may be performed to etch silicon nitride without etching silicon oxide and/or without etching poly-silicon. Etching each of the nitride layers 204 may form a void in each of the tiers. The void may be partially defined by a first surface 222 of an oxide layer 202. The void may be additionally partially defined by a second surface 224 of an adjacent oxide layer 102 of an adjacent tier. The selective etching of the layers 204 may be performed by an etching process. In some embodiments, process chemistries are introduced to the layers 204 to etch the layers 204. Such process chemistries can include hydrofluoric acid (HF), phosphoric acid (H₃PO₄), hot potassium hydroxide (KOH), and/or tetramethylammonium hydroxide (TMAH).

Referring to FIG. 2C, a representation of a third operation 200C is shown. In some embodiments, a metal precursor is introduced into the void. In some embodiments, the metal is deposited on the poly-silicon layer 206 to form a metal silicide layer 208. In some embodiments, the metal precursor is a tungsten-containing precursor. The tungsten-containing precursor may be deposited on the poly-silicon layer 206 to form a tungsten silicide layer. In some embodiments, the metal silicide layer 208 forms a nucleation layer. More details regarding the nucleation layer are described herein below.

Referring to FIG. 2D, a representation of a fourth operation 200D is shown. In some embodiments, the void in each of the tiers formed by the selective etching of nitride layer 204 is back-filled. In some embodiments, a metal layer 210 is formed between each of the oxide layers 202 and the layer 208. In some embodiments, a gas phase reaction mechanism (e.g., such as a CVD technique, etc.) is used to deposit metal between each of the layers 202 and layers 208. As mentioned herein above, each of the layers 208 may form a nucleation layer for the metal. For example, the metal carried in a gaseous precursor and provided into a void may nucleate on the layer 208. The nucleated metal crystals may be grown beginning on the nucleation layer (e.g., layer 208) on a first surface 222 that partially defines the void (e.g., the void left by the selective etching of layers 204) and may grow toward a second surface 224 that partially defines the void opposite the first surface 222. In some embodiments, the nucleated metal crystals may grow from the nucleation layer towards the adjacent oxide layer 202 as shown by the arrows in FIG. 2D. In some embodiments, the metal may not nucleate on the adjacent oxide layer 202 because the metal will tend to naturally nucleate on the nucleation layer (e.g., layer 208). Because the metal layer grows only in one direction, surface tension in the metal may not therefore act upon the oxide layers, so the oxide layers may not be pulled towards one another. In this way, deflection of the tiers may be avoided.

In some embodiments, the metal is a conductive metal such as molybdenum, a molybdenum alloy, tungsten, or a tungsten alloy, etc. In some embodiments, each of the metal layers 210 is to form a conductive line in the tier stack. The conductive lines may be wordlines, such as in a memory array.

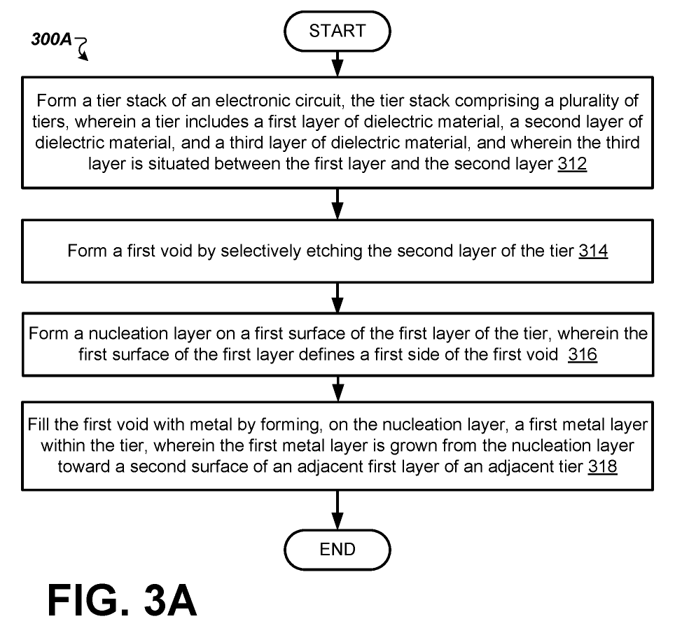

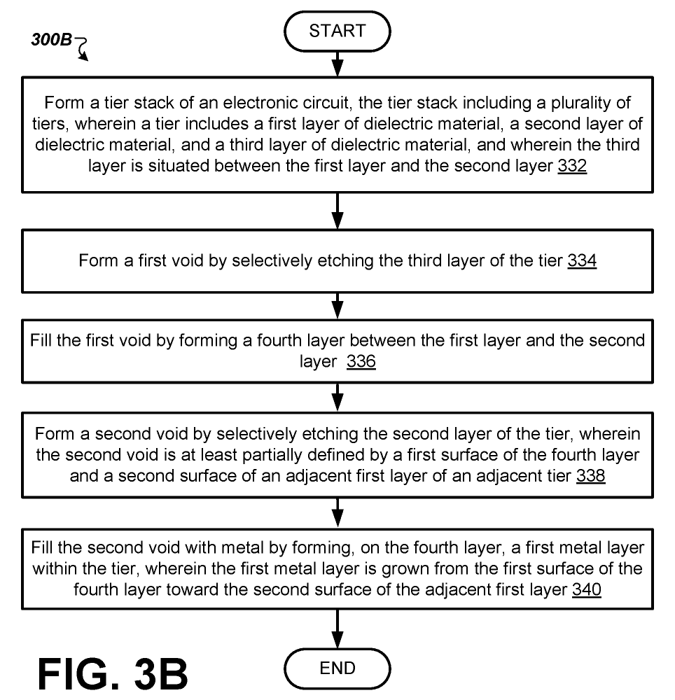

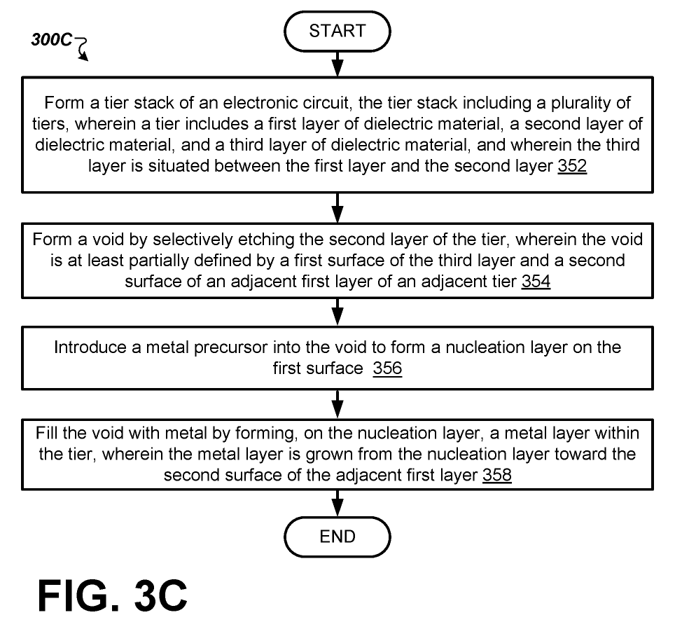

FIGS. 3A-C are flow diagrams of example methods of forming conductive lines of a memory array in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 3A, a flow diagram of an example method 300A for forming wordlines of a memory array is shown. At block 312, a tier stack for an electronic circuit is formed. In some embodiments, the electronic circuit is a memory array such as a flash memory array, a 3D NAND memory array, etc. In some embodiments, a tier of the tier stack may include a first layer of dielectric material, a second layer of dielectric material, and a third layer of dielectric material. The third layer may be situated between the first layer and the second layer. In some embodiments, the tier may be processed to form one or more conductive lines (e.g., wordlines) of an electronic circuit (e.g., a memory array). In some embodiments, the tier stack is formed by multiple deposition processes. For example, a first deposition process may be performed to form a first first layer, a second deposition process may be performed to form a first second layer, a third deposition process may be performed to form a first third layer, a fourth deposition process may be performed to form a second first layer, etc. In some embodiments, the first layer is a metalloid oxide layer (e.g., a silicon oxide layer), the second layer is a metalloid layer (e.g., a poly-silicon layer), and the third layer is a metalloid nitride layer (e.g., a silicon nitride layer) or a carbon-doped nitride layer.

At block 314, a first void is formed by selectively etching the second layer of the tier. In some embodiments, a selective etch process is performed to selectively etch the second layer selective to the first layer and/or selective to the third layer. In some embodiments, an etch process is performed to selectively etch silicon nitride selective to silicon oxide, poly-silicon, and/or carbon-doped nitride. For example, an etch process is performed to etch silicon nitride without etching silicon oxide, poly-silicon, and/or carbon-doped silicon nitride.

At block 316, a nucleation layer is formed on a first surface of the first layer of the tier. In some embodiments, the first surface of the first layer defines a first side of the first void within the tier. In some embodiments, a second surface of an adjacent first layer of an adjacent tier defines a second side of the first void. In some embodiments, the second surface is opposite the first surface (e.g., opposite the first surface across the void, etc.). In some embodiments, the nucleation layer is formed by introducing a metal precursor into the void (e.g., to deposit the metal in the precursor on a poly-silicon layer), or by providing a metal or a metal-based ceramic containing gaseous precursor, etc.

At block 318, the first void is filled with metal by forming, on the nucleation layer, a first metal layer within the tier. In some embodiments, the first metal layer is grown from the nucleation layer toward the second surface of the adjacent first layer of the adjacent tier. In some embodiments, metal (e.g., a metal-containing gaseous precursor, etc.) is provided into the first void of the tier. In some embodiments, the metal nucleates on the nucleation layer on the first surface of the of the first layer. The metal crystals may grow from the nucleation layer on the first surface of the first layer toward the second surface of the adjacent first layer opposite the first surface.

Referring to FIG. 3B, a flow diagram of an example method 300B for forming wordlines of a memory array is shown. At block 332, a tier stack for an electronic circuit is formed. In some embodiments, the electronic circuit is a memory array such as a flash memory array, a 3D NAND memory array, etc. In some embodiments, a tier of the tier stack may include a first layer of dielectric material, a second layer of dielectric material, and a third layer of dielectric material. The third layer may be situated between the first layer and the second layer. In some embodiments, the tier may be processed to form one or more conductive lines (e.g., wordlines) of an electronic circuit (e.g., a memory array). In some embodiments, the tier stack is formed by multiple deposition processes as described herein above. In some embodiments, the first layer is a metalloid oxide layer (e.g., a silicon oxide layer), the second layer is a metalloid layer (e.g., a poly-silicon layer), and the third layer is a metalloid nitride layer (e.g., a silicon nitride layer) or a carbon-doped nitride layer. In some embodiments, the third layer is a sacrificial layer as described herein.

At block 334, a first void is formed by selectively etching the third layer of the tier. In some embodiments, a selective etch process is performed to selectively etch the third layer selective to the first layer and/or selective to the second layer. In some embodiments, an etch process is performed selectively etch silicon nitride selective to silicon oxide, poly-silicon, and/or carbon-doped nitride. For example, an etch process is performed to etch silicon nitride without etching silicon oxide, poly-silicon, and/or carbon-doped silicon nitride.

At block 336, the first void is filled by forming a fourth layer between the first layer and the second layer of the tier. In some embodiments, the fourth layer is a metal layer or a metal-based ceramic layer. For example, the fourth layer may be a titanium layer or a titanium-nitride layer. In some embodiments, the fourth layer is formed by providing or depositing the metal or metal-based ceramic into the first void. In some embodiments, the fourth layer forms a nucleation layer as described herein.

At block 338, a second void is formed by selectively etching the second layer of the tier. In some embodiments, a selective etch process is performed to selectively etch the second layer selective to the first layer and/or the fourth layer. In some embodiments, an etch process is performed to selectively etch silicon nitride selective to silicon oxide, titanium, and/or titanium nitride. For example, an etch process is performed to etch silicon nitride without etching silicon oxide, titanium, and/or titanium nitride. In some embodiments, the second void is at least partially defined by a first surface of the fourth layer and a second surface of an adjacent first layer of an adjacent tier.

At block 340, the second void is filled with metal by forming, on the fourth layer, a metal layer. In some embodiments, the first metal layer is grown from the first surface of the fourth layer toward the second surface of the adjacent first layer. In some embodiments, a metal (e.g., a metal-containing gaseous precursor, etc.) is provided into the void of the tier. In some embodiments, the metal nucleates on the nucleation layer (e.g., the fourth layer formed at block 336) on the first surface of the fourth layer. The metal crystals may grow from the first surface (e.g., the nucleation layer) toward the second surface of the adjacent first layer opposite the first surface.

Referring to FIG. 3C, a flow diagram of an example method 300C for forming wordlines of a memory array is shown. At block 352, a tier stack for an electronic circuit is formed. In some embodiments, the electronic circuit is a memory array such as a flash memory array, a 3D NAND memory array, etc. In some embodiments, a tier of the tier stack may include a first layer of dielectric material, a second layer of dielectric material, and a third layer of dielectric material. The third layer may be situated between the first layer and the second layer. In some embodiments, the tier may be processed to form one or more conductive lines (e.g., wordlines) of an electronic circuit. In some embodiments, the tier stack is formed by multiple deposition processes as described herein above. In some embodiments, the first layer is a metalloid oxide layer (e.g., a silicon oxide layer), the second layer is a metalloid layer (e.g., a poly-silicon layer), and the third layer is a metalloid nitride layer (e.g., a silicon nitride layer).

At block 354, a void is formed by selectively etching the second layer of the tier. In some embodiments, a selective etch process is performed to selectively etch the second layer selective to the first layer and/or the third layer. In some embodiments, an etch process is performed to selectively etch silicon nitride selective to silicon oxide and/or poly-silicon. For example, an etch process is performed to etch silicon nitride without etching silicon oxide or poly-silicon. In some embodiments, the void is at least partially defined by a first surface of the third layer and a second surface of an adjacent first layer of an adjacent tier.

At block 356, a metal precursor is introduced into the void to form a nucleation layer on the first surface. In some embodiments, the metal precursor is a tungsten-containing precursor. In some examples, the metal precursor may be deposited on the poly-silicon third layer to form a metal-silicide layer. Specifically, the tungsten-containing precursor may be deposited on the poly-silicon of the third layer to form a tungsten silicide layer.

At block 358, the void is filled with metal by forming, on the nucleation layer, a metal layer within the tier. In some embodiments, the metal layer is grown from the nucleation layer toward the second surface of the adjacent first tier. In some embodiments, a metal (e.g., a metal-containing gaseous precursor, etc.) is provided into the void of the tier. In some embodiments, the metal nucleates on the nucleation layer on the first side of the void. The metal crystals may grow from the nucleation layer on the first side of the void toward the second side of the void opposite the first side.

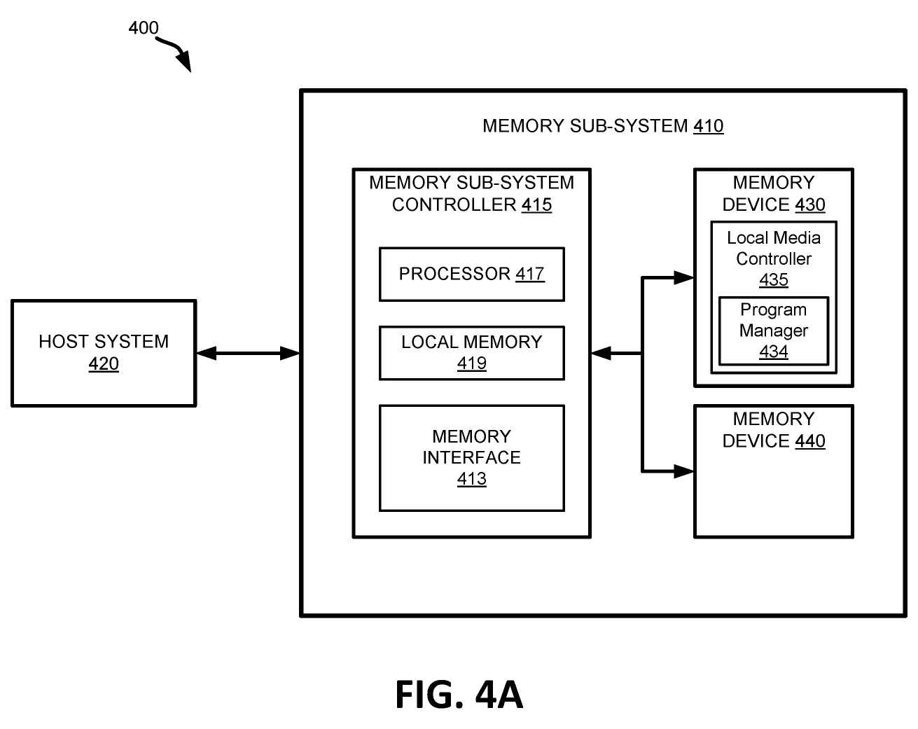

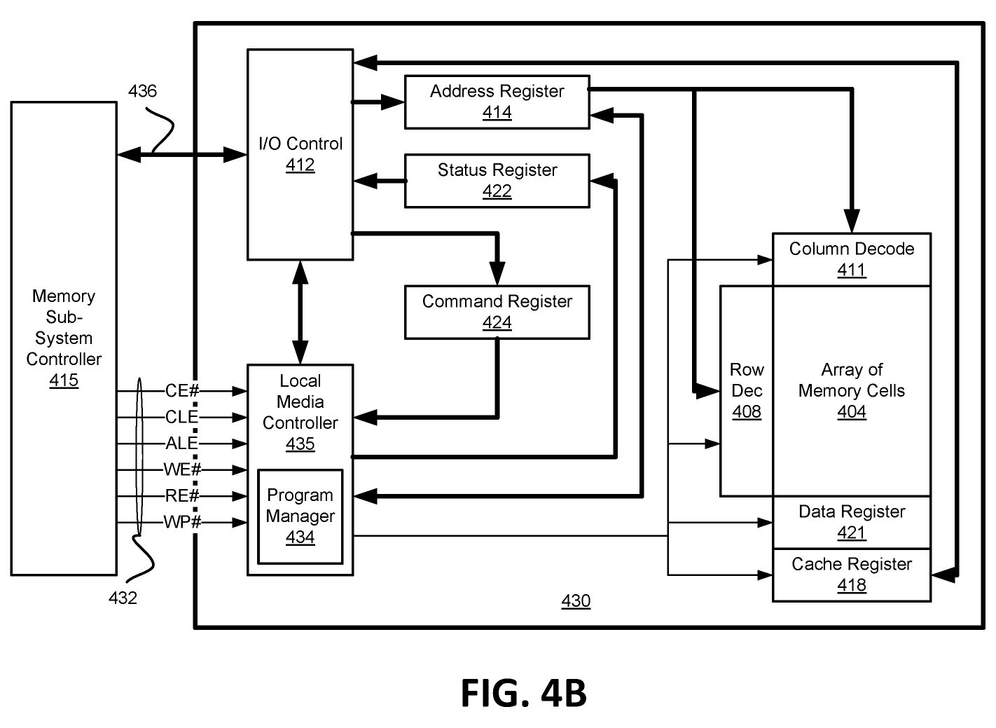

FIG. 4A illustrates an example computing system 400 that includes a memory sub-system 410 in accordance with some embodiments of the present disclosure. In some embodiments, one or more components of computing system 400 include conductive lines manufactured according to a method described herein above. The memory sub-system 410 can include media, such as one or more volatile memory devices (e.g., memory device 440), one or more non-volatile memory devices (e.g., memory device 430), or a combination of such.

A memory sub-system 410 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 400 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 400 can include a host system 420 that is coupled to one or more memory sub-systems 410. In some embodiments, the host system 420 is coupled to multiple memory sub-systems 410 of different types. FIG. 4A illustrates one example of a host system 420 coupled to one memory sub-system 410. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 420 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 420 uses the memory sub-system 410, for example, to write data to the memory sub-system 410 and read data from the memory sub-system 410.

The host system 420 can be coupled to the memory sub-system 410 via a physical host interface. Examples of a physical host interface include a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 420 and the memory sub-system 410. The host system 420 can further utilize an NVM Express (NVMe) interface to access components (e.g., memory devices 430) when the memory sub-system 410 is coupled with the host system 420 by the physical host interface (e.g., PCIe bus). The physical host interface can provide an interface for passing control, address, data, and other signals between the memory sub-system 410 and the host system 420. FIG. 4A illustrates a memory sub-system 410 as an example. In general, the host system 420 can access multiple memory sub-systems via a same communication connection, multiple separate communication connections, and/or a combination of communication connections.

The memory devices 430, 440 can include any combination of the different types of non-volatile memory devices and/or volatile memory devices. The volatile memory devices (e.g., memory device 440) can be random access memory (RAM), such as dynamic random access memory (DRAM) and synchronous dynamic random access memory (SDRAM).

Some examples of non-volatile memory devices (e.g., memory device 430) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 430 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 430 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 430 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 430 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 415 (or controller 415 for simplicity) can communicate with the memory devices 430 to perform operations such as reading data, writing data, or erasing data at the memory devices 430 and other such operations. The memory sub-system controller 415 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 415 can be a microcontroller, special purpose logic circuitry (e.g., a field programmable gate array (FPGA), an application specific integrated circuit (ASIC), etc.), or other suitable processor.

The memory sub-system controller 415 can include a processing device, which includes one or more processors (e.g., processor 417), configured to execute instructions stored in a local memory 419. In the illustrated example, the local memory 419 of the memory sub-system controller 415 includes an embedded memory configured to store instructions for performing various processes, operations, logic flows, and routines that control operation of the memory sub-system 410, including handling communications between the memory sub-system 410 and the host system 420.

In some embodiments, the local memory 419 can include memory registers storing memory pointers, fetched data, etc. The local memory 419 can also include read-only memory (ROM) for storing micro-code. While the example memory sub-system 410 in FIG. 4A has been illustrated as including the memory sub-system controller 415, in another embodiment of the present disclosure, a memory sub-system 410 does not include a memory sub-system controller 415, and can instead rely upon external control (e.g., provided by an external host, or by a processor or controller separate from the memory sub-system).

In general, the memory sub-system controller 415 can receive commands or operations from the host system 420 and can convert the commands or operations into instructions or appropriate commands to achieve the desired access to the memory devices 430. The memory sub-system controller 415 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 430. The memory sub-system controller 415 can further include host interface circuitry to communicate with the host system 420 via the physical host interface. The host interface circuitry can convert the commands received from the host system into command instructions to access the memory devices 430 as well as convert responses associated with the memory devices 430 into information for the host system 420.

The memory sub-system 410 can also include additional circuitry or components that are not illustrated. In some embodiments, the memory sub-system 410 can include a cache or buffer (e.g., DRAM) and address circuitry (e.g., a row decoder and a column decoder) that can receive an address from the memory sub-system controller 415 and decode the address to access the memory devices 430.

In some embodiments, the memory devices 430 include local media controllers 435 that operate in conjunction with memory sub-system controller 415 to execute operations on one or more memory cells of the memory devices 430. An external controller (e.g., memory sub-system controller 415) can externally manage the memory device 430 (e.g., perform media management operations on the memory device 430). In some embodiments, memory sub-system 410 is a managed memory device, which is a raw memory device 430 having control logic (e.g., local media controller 435) on the die and a controller (e.g., memory sub-system controller 415) for media management within the same memory device package. An example of a managed memory device is a managed NAND (MNAND) device.

The memory sub-system 410 includes a memory interface component 413 that can handle interactions of memory sub-system controller 415 with the memory devices of memory sub-system 410, such as memory device 430. For example, memory interface component 413 can receive data from memory device 430, such as data retrieved in response to a read operation or a write operation. In some examples, the memory sub-system controller 415 can include a processor 417 (processing device) configured to execute instructions stored in local memory 419 for performing the operations described herein.

In some embodiments, memory device 430 includes a program manager 434. In some embodiments, local media controller 435 includes at least a portion of program manager 434 and is configured to perform various memory functions. In some embodiments, the program manager 434 is part of the host system 410, an application, or an operating system. Further details with regards to the operations of program manager 434 are described below. In some embodiments, program manager 434 is implemented on memory device 430 using firmware, hardware components, or a combination of the above.

FIG. 4B is a simplified block diagram of a first apparatus, in the form of a memory device 430, in communication with a second apparatus, in the form of a memory sub-system controller 415 of a memory sub-system (e.g., memory sub-system 410 of FIG. 4A), according to an embodiment. In some embodiments, one or more components of memory device 430 include conductive lines manufactured according to a method described herein above. Some examples of electronic systems include personal computers, personal digital assistants (PDAs), digital cameras, digital media players, digital recorders, games, appliances, vehicles, wireless devices, mobile telephones and the like. The memory sub-system controller 415 (e.g., a controller external to the memory device 430), can be a memory controller or other external host device.

Memory device 430 includes an array of memory cells 404 logically arranged in rows and columns. Memory cells of a logical row are typically connected to the same access line (e.g., a wordline) while memory cells of a logical column are typically selectively connected to the same data line (e.g., a bit line). A single access line can be associated with more than one logical row of memory cells and a single data line can be associated with more than one logical column. Memory cells (not shown in FIG. 4B) of at least a portion of array of memory cells 404 are capable of being programmed to one of at least two target data states.

Row decode circuitry 408 and column decode circuitry 411 are provided to decode address signals. Address signals are received and decoded to access the array of memory cells 404. Memory device 430 also includes input/output (I/O) control circuitry 412 to manage input of commands, addresses and data to the memory device 430 as well as output of data and status information from the memory device 430. An address register 414 is in communication with I/O control circuitry 412 and row decode circuitry 408 and column decode circuitry 411 to latch the address signals prior to decoding. A command register 424 is in communication with I/O control circuitry 412 and local media controller 435 to latch incoming commands.

A controller (e.g., the local media controller 435 internal to the memory device 430) controls access to the array of memory cells 404 in response to the commands and generates status information for the external memory sub-system controller 415, i.e., the local media controller 435 is configured to perform access operations (e.g., read operations, programming operations and/or erase operations) on the array of memory cells 404. The local media controller 435 is in communication with row decode circuitry 408 and column decode circuitry 411 to control the row decode circuitry 408 and column decode circuitry 411 in response to the addresses. In at least one embodiment, local media controller 435 includes program manager 434, which can implement the bad block mapping operations with respect to memory device 430, as described herein.

The local media controller 435 is also in communication with a cache register 418. Cache register 418 latches data, either incoming or outgoing, as directed by the local media controller 435 to temporarily store data while the array of memory cells 404 is busy writing or reading, respectively, other data. During a programming operation (e.g., a write operation), data can be passed from the cache register 418 to the data register 421 for transfer to the array of memory cells 404; then new data can be latched in the cache register 418 from the I/O control circuitry 412. During a read operation, data can be passed from the cache register 418 to the I/O control circuitry 412 for output to the memory sub-system controller 415; then new data can be passed from the data register 421 to the cache register 418. The cache register 418 and/or the data register 421 can form (e.g., can form a portion of) a page buffer of the memory device 430. A page buffer can further include sensing devices (not shown in FIG. 4B) to sense a data state of a memory cell of the array of memory cells 404, e.g., by sensing a state of a data line connected to that memory cell. A status register 422 can be in communication with I/O control circuitry 412 and the local memory controller 435 to latch the status information for output to the memory sub-system controller 415.

Memory device 430 receives control signals at the memory sub-system controller 415 from the local media controller 435 over a control link 432. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 432 depending upon the nature of the memory device 430. In at least one embodiment, memory device 430 receives command signals (which represent commands), address signals (which represent addresses), and data signals (which represent data) from the memory sub-system controller 415 over a multiplexed input/output (I/O) bus 436 and outputs data to the memory sub-system controller 415 over I/O bus 436.

For example, the commands can be received over input/output (I/O) pins [7:0] of I/O bus 436 at I/O control circuitry 412 and can then be written into command register 424. The addresses can be received over input/output (I/O) pins [7:0] of I/O bus 436 at I/O control circuitry 412 and can then be written into address register 414. The data can be received over input/output (I/O) pins [7:0] for an 8-bit device or input/output (I/O) pins [15:0] for a 16-bit device at I/O control circuitry 412 and then can be written into cache register 418. The data can be subsequently written into data register 421 for programming the array of memory cells 404.

In at least one embodiment, cache register 418 can be omitted, and the data can be written directly into data register 421. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 430 by an external device (e.g., the memory sub-system controller 415), such as conductive pads or conductive bumps as are commonly used.

In some implementations, additional circuitry and signals can be provided, and that the memory device 430 of FIG. 4B has been simplified. It should be recognized that the functionality of the various block components described with reference to FIG. 4B cannot necessarily be segregated to distinct components or component portions of an integrated circuit device. For example, a single component or component portion of an integrated circuit device could be adapted to perform the functionality of more than one block component of FIG. 4B. Alternatively, one or more components or component portions of an integrated circuit device could be combined to perform the functionality of a single block component of FIG. 4B. Additionally, while specific I/O pins are described in accordance with popular conventions for receipt and output of the various signals, it is noted that other combinations or numbers of I/O pins (or other I/O node structures) can be used in the various embodiments.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method, comprising:
forming a tier stack of an electronic circuit, the tier stack comprising a plurality of tiers, wherein a tier of the plurality of tiers comprises a first layer of dielectric material, a second layer of dielectric material, and a third layer of dielectric material, and wherein the third layer is situated between the first layer and the second layer;
forming a first void by selectively etching the second layer of the tier;
forming a nucleation layer on a first surface of the first layer of the tier, wherein the first surface of the first layer of the tier defines a first side of the first void; and
filling the first void with metal by forming, on the nucleation layer, a first metal layer within the tier, wherein the first metal layer is grown from the nucleation layer toward a second surface of an adjacent first layer of an adjacent tier, and wherein the second surface defines a second side of the first void and is opposite the first surface.

2. The method of claim 1, further comprising:
forming a second void by selectively etching the third layer of the tier; and
filling the second void with at least one of: a metal or a metal-based ceramic, by forming a fourth layer between the first layer and the second layer, wherein the fourth layer comprises the nucleation layer.

3. The method of claim 1, further comprising:
introducing a metal precursor into the first void to form the nucleation layer.

4. The method of claim 1, wherein the first layer comprises a metalloid oxide and wherein the second layer comprises a metalloid nitride.

5. The method of claim 4, wherein the selective etching of the second layer of the tier comprises selectively etching the metalloid nitride selective to the metalloid oxide.

6. The method of claim 1, wherein the third layer comprises a metalloid .

7. The method of claim 1, wherein the nucleation layer comprises titanium nitride or tungsten silicide, and wherein the first metal layer comprises a molybdenum alloy or a tungsten alloy.

8. The method of claim 1, wherein the electronic circuit comprises a memory array, and wherein the tier stack forms a plurality of conductive lines.

9. A method, comprising:
forming a tier stack of an electronic circuit, the tier stack comprising a plurality of tiers, wherein a tier of the plurality of tiers comprises a first layer of dielectric material, a second layer of dielectric material, and a third layer of dielectric material, and wherein the third layer is situated between the first layer and the second layer;
forming a first void by selectively etching the third layer of the tier;
filling the first void by forming a fourth layer between the first layer and the second layer;
forming a second void by selectively etching the second layer of the tier, wherein the second void is at least partially defined by a first surface of the fourth layer and a second surface of an adjacent first layer of an adjacent tier; and
filling the second void with metal by forming, on the fourth layer, a first metal layer within the tier, wherein the first metal layer is grown from the first surface of the fourth layer toward the second surface of the adjacent first layer.

10. The method of claim 9, wherein the first layer comprises a metalloid oxide and wherein the second layer comprises a metalloid nitride.

11. The method of claim 9, wherein the third layer comprises carbon-doped nitride.

12. The method of claim 9, wherein the fourth layer comprises titanium nitride.

13. The method of claim 9, wherein the first metal layer comprises a molybdenum alloy or a tungsten alloy, and wherein the fourth layer forms a nucleation layer with respect to the first metal layer.

14. The method of claim 9, wherein the electronic circuit comprises a memory array, and wherein the tier stack forms a plurality of conductive lines.

15. A method, comprising:
forming a tier stack of an electronic circuit, the tier stack comprising a plurality of tiers, wherein a tier of the plurality of tiers comprises a first layer of dielectric material, a second layer of dielectric material, and a third layer of dielectric material, and wherein the third layer is situated between the first layer and the second layer;
forming a void by selectively etching the second layer of the tier, wherein the void is at least partially defined by a first surface of the third layer of the tier and a second surface of an adjacent first layer of an adjacent tier;
introducing a metal precursor into the void to form a nucleation layer on the first surface; and
filling the void with metal by forming, on the nucleation layer, a metal layer within the tier, wherein the metal layer is grown from the nucleation layer toward the second surface of the adjacent first layer.

16. The method of claim 15, wherein the first layer comprises a metalloid oxide and wherein the second layer comprises a metalloid nitride.

17. The method of claim 15, wherein the third layer comprises a metalloid.

18. The method of claim 15, wherein the metal precursor comprises a tungsten-containing precursor, and wherein the nucleation layer comprises tungsten silicide.

19. The method of claim 15, wherein the metal layer comprises a molybdenum alloy or a tungsten alloy.

20. The method of claim 15, wherein the electronic circuit comprises a memory array, and wherein the tier stack forms a plurality of conductive lines.
